(19) United States
(12) Patent Application Publication
(10) Pub. No.: US 2009/0199768 A1
(43) Pub. Date: Aug. 13, 2009

(54) MAGNETIC DOMAIN PATTERNING USING PLASMA ION IMPLANTATION

(76) Inventors: Steven Verhaverbeke, San Francisco, CA (US); Nety M. Krishna, Sunnyvale, CA (US); Omkaram Nalamasu, San Jose, CA (US); Mahalingam Venkatesan, San Jose, CA (US)

Correspondence Address: Patent Counsel, MS/2061;Applied Materials, Inc., Legal Affairs Dept., P.O. BOX 450A, Santa Clara, CA, 95052, US

(21) Appl. No.: 12/029,601

(22) Filed: Feb. 12, 2008

(51) Int. Cl. B44C 1/22; C23C 16/00

(52) U.S. Cl. 118/728; 216/22

(57) ABSTRACT

A method for defining magnetic domains in a magnetic thin film on a substrate, includes: coating the magnetic thin film with a resist; patterning the resist, wherein areas of the magnetic thin film are substantially uncovered; and exposing the magnetic thin film to a plasma, wherein plasma ions penetrate the substantially uncovered areas of the magnetic thin film, rendering the substantially uncovered areas non-magnetic. A tool for this process comprises: a vacuum chamber held at earth potential; a gas inlet valve configured to leak controlled amounts of gas into the chamber; a disk mounting device configured to (1) fit within the chamber, (2) hold a multiplicity of disks, spacing the multiplicity of disks wherein both sides of each of the multiplicity of disks is exposed and (3) make electrical contact to the multiplicity of disks; and a radio frequency signal generator electrically coupled to the disk mounting device and the chamber, whereby a plasma can be ignited in the chamber and the disks are exposed to plasma ions uniformly on both sides.

### FIELD OF THE INVENTION

The present invention relates generally to definition of magnetic domains in magnetic information storage media, and more particularly to a method of defining magnetic domains in magnetic thin films by using plasma ion implantation.

### BACKGROUND OF THE INVENTION

There is an ever present need for higher density information storage media for computers. Currently, the prevalent storage media is the hard disk drive (HDD). An HDD is a non-volatile storage device which stores digitally encoded data on rapidly rotating disks with magnetic surfaces. The disks are circular, with a central hole. The disks are made from a non-magnetic material, usually glass or aluminum, and are coated on both sides with magnetic thin films, such as cobalt-based alloy thin films. HDDs record data by magnetizing regions of the magnetic film with one of two particular orientations, allowing binary data storage in the film. The stored data is read by detecting the orientation of the magnetized regions of the film. A typical HDD design consists of a spindle which holds multiple disks, spaced sufficiently to allow read-write heads to access both sides of all of the disks. The disks are fixed to the spindle by clamps inserted into the central holes in the disks. The disks are spun at very high speeds. Information is written onto and read off a disk as it rotates past the read-write heads. The heads move in very close proximity to the surface of the magnetic thin film. The read-write head is used to detect and/or modify the magnetization of the material immediately underneath it. There is one head for each magnetic disk surface on the spindle. An arm moves the heads across the disks as they spin, allowing each head to access almost the entire surface of a disk.

The magnetic surface of each disk is divided into many small sub-micrometer-sized magnetic regions, referred to as magnetic domains, each of which is used to encode a single binary unit of information, referred to as a bit. Each magnetic region forms a magnetic dipole which generates a highly localized magnetic field. The write head magnetizes a magnetic region by generating a strong local magnetic field while in very close proximity to the magnetic thin film. The read head detects the orientation of the magnetic field in each region.

Where domains with different spin orientations meet there is a region referred to as a Bloch wall in which the spin orientation goes through a transition from the first orientation to the second. The width of this transition region limits the areal density of information storage. Consequently, there is a need to overcome the limit due to the width of Bloch walls.

To overcome the limit due to Bloch wall width in continuous magnetic thin films the domains can be physically separated by a non-magnetic region (which can be narrower than the width of a Bloch wall in a continuous magnetic thin film). The following approaches have been used to provide magnetic storage media with improved areal density of information storage. These approaches have single bit magnetic domains that are completely separate from each other, either by depositing the magnetic domains as separate islands or by remove material from a continuous magnetic film to physically separate the magnetic domains.

A disk is coated with a seed layer followed by a resist. The resist is patterned to define magnetic domains, exposing the seed layer where magnetic domains are to be formed. A magnetic thin film is then electroplated onto the exposed regions of the seed layer. However, there are problems with the composition and quality of the electrodeposited magnetic films and with the scalability of the process for high volume manufacturing of HDDs. Sputter-deposited Co—Pt and Co—Pd alloy thin films are currently preferred over electrodeposited Co—Pt due to better corrosion resistance and more controllable magnetic properties.

In an alternative process a disk coated with a sputter-deposited magnetic thin film is covered with a layer of resist which is patterned to define magnetic domains. The pattern is transferred into the magnetic thin film by a sputter dry etch process. However, the sputter-etch process leaves an undesirable build-up of residue on the process chamber walls. Furthermore, leaving a residue free disk surface is a challenge following the sputter-etch process. (A very flat, residue-free disk surface is required considering that the read-write head travels only several tens of nanometers above the disk surface at very high speed.) Also, the HDD disks require patterning of magnetic thin films on both sides and many semiconductor type processes and equipment (i.e. sputter etch) can only process one side at once. These problems affect production yields and can contribute to HDD failures. Consequently, there is a need for more production-worthy methods—cost-effective and compatible with high-volume manufacturing—for patterning the magnetic domains.

Another approach is to create non-magnetic regions in a continuous magnetic thin film to separate the magnetic domains. An advantage of such a method is that the surface of the finished disk is planar and better suited for use in an HDD. Such a method is to pattern the magnetic domains using ion implantation to create non-magnetic areas to separate the magnetic domains. The energetic ions disorder the magnetic material, rendering the material non-magnetic. Although, there are some non-magnetic materials, such as ordered FePt₃, which can be made magnetic by ion irradiation, in which case ion irradiation is used to directly define the magnetic domains. However, patterning by ion irradiation can suffer from the following disadvantages: (1) ion implanter tools are configured to irradiate only one side of a substrate at once; (2) and the process is slow, due to the limited ion current available from an ion implanter ion source. Therefore, there remains a need for methods for patterning the magnetic domains which are cost effective and compatible with high volume manufacturing.

### SUMMARY OF THE INVENTION

The concepts and methods of the invention allow for high volume manufacturing of magnetic media where the magnetic domains on the disks are directly patterned. Direct patterning of the magnetic domains allows for higher density data storage than is available in continuous magnetic thin films. According to aspects of the invention, a method for defining magnetic domains in a magnetic thin film on a substrate includes: (1) coating the magnetic thin film with a resist; (2) patterning the resist, wherein areas of the magnetic thin film are substantially uncovered; and (3) exposing the magnetic thin film to a plasma, wherein plasma ions penetrate the substantially uncovered areas of the magnetic thin film, rendering the substantially uncovered areas non-magnetic. The preferred method of patterning the resist is a nanoimprint lithography process.

The methods of the invention are applied to advantage in high volume manufacturing of thin film magnetic disks used in hard disk drives. The present invention provides high manufacturing throughput by simultaneously processing both sides of the disks using a high throughput plasma ion implantation tool. According to further aspects of the invention, a method for defining magnetic domains in magnetic thin films on both sides of a disk includes: (1) coating both sides of the disk with a resist; (2) patterning the resist, wherein areas of the magnetic thin film are substantially uncovered; and (3) simultaneously exposing the magnetic thin film on both sides of the disk to a plasma, wherein plasma ions penetrate the substantially uncovered areas of the magnetic thin film, rendering the substantially uncovered areas non-magnetic.

Although a double side plasma ion implant is preferred, a single side plasma ion implant can be used without departing from the spirit of the invention. In the single side plasma ion implant a first side will be implanted, then the disk will be flipped over and the second side will be implanted.

The invention includes a plasma ion implantation tool configured for simultaneous processing of both sides of disks. The tool comprises: (1) a vacuum chamber held at earth potential; (2) a gas inlet valve configured to leak controlled amounts of gas into the chamber; (3) a disk mounting device configured to (a) fit within the chamber, (b) hold a multiplicity of disks, spacing the multiplicity of disks wherein both sides of each of the multiplicity of disks is exposed and (c) make electrical contact to the multiplicity of disks; and (4) a radio frequency signal generator electrically coupled to the disk mounting device and the chamber, whereby a plasma can be ignited in the chamber and the disks are exposed to plasma ions uniformly on both sides.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is process flow chart of the invention;

FIG. 2 is a schematic of a process chamber of the invention, showing a first disk holder apparatus of the invention;

FIG. 3 is a second disk holder of the invention;

FIG. 4 is a cross-sectional representation of the resist after nanoimprint lithography, according to the invention.

### DETAILED DESCRIPTION OF THE PREFERRED EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

In general, the present invention contemplates using plasma ion implantation and a resist mask to pattern closely spaced magnetic domains in a magnetic thin film. This method is applicable to hard disk drive fabrication, allowing very high areal density information storage. A tool for implementing this method is described.

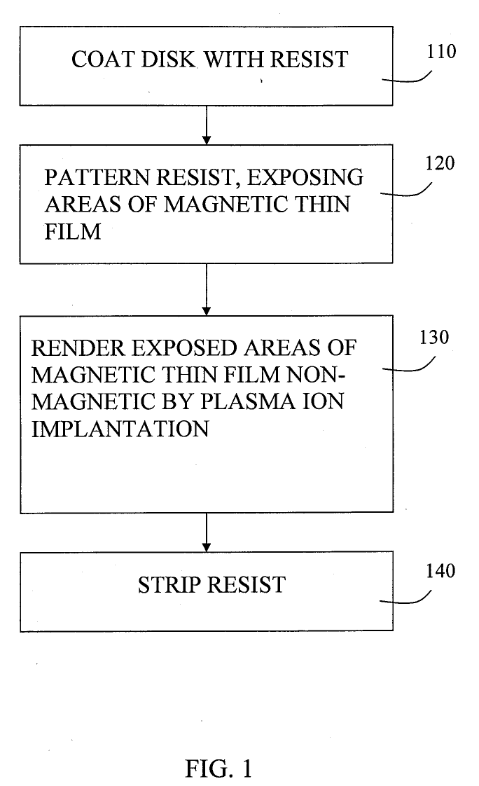

The process of the invention is shown in FIG. 1. The process for forming closely spaced magnetic domains, separated by non-magnetic material, in a magnetic thin film includes the following steps: (1) coat disk with resist (110); (2) pattern resist, substantially exposing areas of the magnetic thin film (120); (3) render substantially exposed areas of the magnetic thin film non-magnetic by plasma ion implantation (130); and (4)strip resist (140). The method may optionally include a descum and ash in the plasma ion implantation chamber after plasma ion implantation and prior to resist strip. Also, a buff or polish may be included after resist strip to ensure a residue-free surface. For example, a brush scrubber step, such as carried out with a PVA brush, or other appropriate type of brush, may be used. Alternatively, a polyurethane cloth or pad buff or polish may be used.

The above process may also include the extra step of a laser or flash anneal to drive the plasma ion implanted species into the thin film. A rapid thermal anneal or furnace process may also be used. (The laser or flash anneal differs from the rapid thermal anneal or furnace process in that only the surface of the disk is subject to the thermal excursion in the former.) Furthermore, thermal processing can be used to force the implanted species into the grain boundaries in the magnetic thin film. (Each magnetic domain currently comprises many hundreds of individual grains.) The implanted species are locked in place in the grain boundaries so that they do not move during the normal lifetime of the disk.

A preferred method for patterning the resist is a nanoimprint lithography method. There are two well known types of nanoimprint lithography that are applicable to the present invention. The first is thermoplastic nanoimprint lithography (T-NIL), which includes the following steps: (1) coat the substrate with a thermoplastic polymer resist; (2) bring a mold with the desired three-dimensional pattern into contact with the resist and apply a prescribed pressure; (3) heat the resist above its glass transition temperature; (4) when the resist goes above its glass transition temperature the mold is pressed into the resist; (5) cool the resist and separate the mold from the resist, leaving the desired three-dimensional pattern in the resist.

The second type of nanoimprint lithography is photo nanoimprint lithography (P-NIL), which includes the following steps: (1) a photo-curable liquid resist is applied to the substrate; (2) a transparent mold, with the desired three-dimensional pattern, is pressed into the liquid resist until the mold makes contact with the substrate; (3) the resist is cured in ultraviolet light, becoming a solid; (4) the mold is separated from the resist, leaving the desired three-dimensional pattern in the resist. In P-NIL the mold is made of a transparent material such as fused silica.

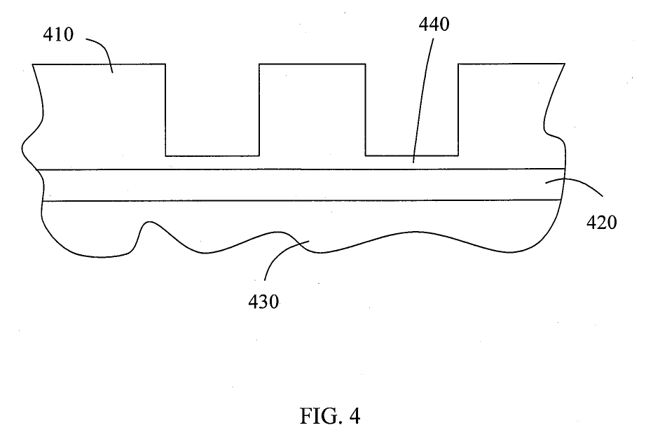

FIG. 4 shows a cross-sectional representation of the resist after nanoimprint lithography. The patterned resist 410 on magnetic thin film 420 on substrate 430 is shown having patterned areas 440 where the resist has been substantially displaced. A typical thickness of resist layer 410 is about 500 nm. However, areas 440 have a small amount of resist left covering the surface of the magnetic thin film. This is typical for a nanoimprint process. When using a photoresist pattern as a mask for ion implantation, it is not necessary for the entire photoresist layer to be removed in the areas where the species will be implanted. However, the remaining layer should be thin enough not to cause a substantial barrier for the implant species. Furthermore, the contrast between the areas with thick resist and thin remaining resist should be large enough so the resist in the areas that have the thick remaining resist is capable of stopping the ion species before they reach the magnetic thin film. Alternatively, the remaining photoresist in areas 440 can be removed with an isotropic resist removal process such as a descum or a slight ash or any other appropriate technique.

The nanoimprint lithography process can be implemented using a full disk nanoimprint scheme, where the mold is large enough to imprint one entire surface. Alternatively, a step and repeat imprint process can be used. In the present invention a full disk scheme is preferred. The nanoimprint process can also be performed with both sides at once. For example, the disk may first be coated with a photoresist layer on both sides. Then the disk goes into a press where molds are pressed against both sides of the disk to imprint the desired pattern on both sides of the disk simultaneously.

Conventional photolithographic processes may also be used, in which case photoresist is spun on the disks, followed by exposure of the resist through a mask, and development of the exposed resist.

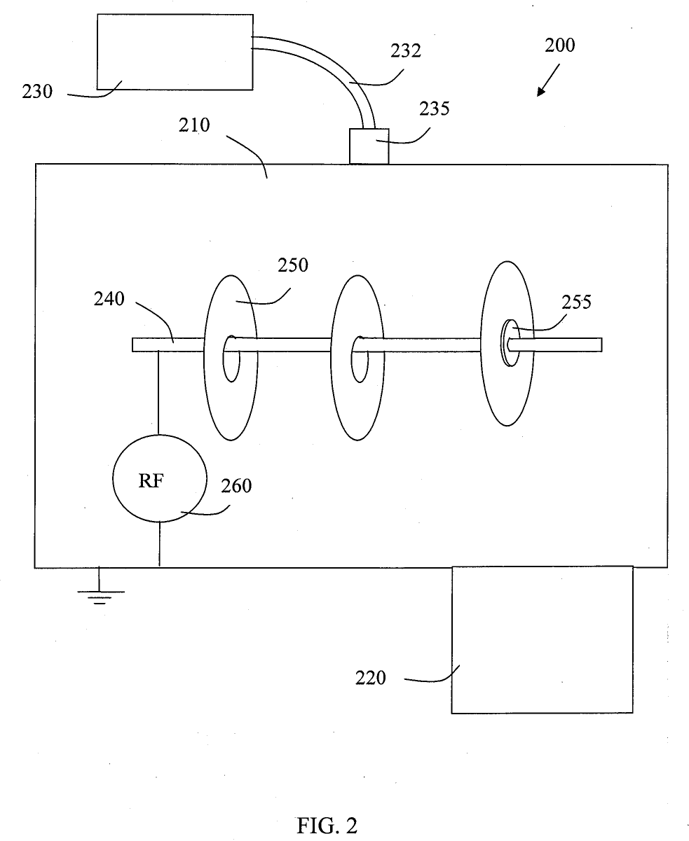

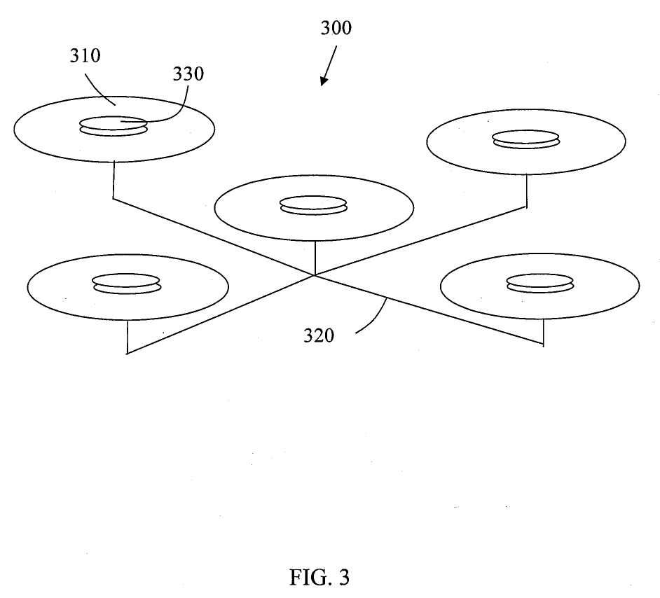

After the patterning step 120 the disks have a patterned resist which leaves areas of the magnetic thin film exposed. The resist protects the remaining surface from the next step—plasma ion implantation 130. Plasma implantation is ideal for providing high implant doses at low energies. Since the sputtered magnetic thin films are typically only tens of nanometers thick the low ion energies are effective and the high dose provides high throughput. Furthermore, as is clear from FIGS. 2 and 3, plasma ion implantation of both sides of the disks can be carried out at the same time. Although a double side plasma ion implant is preferred, a single side plasma ion implant can be used without departing from the spirit of the invention. In the single side plasma ion implant a first side will be implanted, then the disk will be flipped over and the second side will be implanted.

A plasma ion implantation tool 200 configured for handling HDD disks is shown in FIG. 2. The chamber 210 is maintained under vacuum by vacuum pump 220. Gas supply 230 is connected by pipe 232 and valve 235 to the chamber 210. More than one gas may be supplied through valve 235 and multiple gas supplies and valves may be used. A rod 240 holds disks 250. A radio frequency (RF) power supply 260 is connected between the rod 240 and the wall of the chamber 210 (the chamber wall is connected to an electrical earth). In addition to the RF power supply an impedance matching device and a power supply for applying a direct current (DC) bias may be included. The rod 240 may be coated with graphite or silicon to protect it from the plasma. Furthermore, the rod and its surface are highly conductive to facilitate a good electrical contact between the rod and the disks. The disks 250 can be fixed in place using clamps 255 or other means; the clamps 255 will not only fix the disks 250 in place but also ensure a good electrical connection between the disks 250 and the rod 240. The rod will carry many disks (only three disks 250 are shown for ease of illustration). Furthermore, the chamber 210 can be configured to hold many rods loaded with disks for simultaneous plasma ion implantation. The rods 240 are readily moved in and out of the chamber 210.

Processing of the disks in the plasma ion implantation tool 200 proceeds as follows: (1) the disks 250 are loaded onto the rod 240; (2) the rod 240 is loaded into the chamber 210; (3) the vacuum pump 220 operates to achieve a desired chamber pressure; (4) a desired gas is leaked into the chamber from gas supply 230 through valve 235 until the desired pressure is reached; (5) the RF power supply 260 is operated so as to ignite a plasma which surrounds the surfaces of all of the disks 250 and the DC power supply can be used to control the energy of the ions that are implanted into the magnetic thin film. RF biasing may also be used.

Ions that can be readily implanted from a plasma and that will be effective in rendering the typical sputtered magnetic thin films, such as Co—Pt and Co—Pd, non-magnetic are: oxygen, fluorine, boron, phosphorus, tungsten, arsenic, hydrogen, helium, argon, nitrogen, vanadium and silicon ions. This list is not intended to be exhaustive—any ion readily formed in a plasma and effective in rendering a thin film non-magnetic (or magnetic in the case of materials such as FePt₃) will suffice. Ideally, the ion that can change areas of the magnetic thin film into thermally stable non-magnetic areas at the lowest dose will be preferred.

The energy of ions available from a plasma implantation process is in the range of 100 eV to 15 keV. However, for implanting into the magnetic thin films, which are tens of nanometers thick, the desirable energy range is 1 keV to 5 keV. Here it is assumed that singly ionized species are predominant in the plasma.

FIG. 3 shows an alternative holder for plasma ion implantation of the disks in a chamber as shown in FIG. 2. Holder 300 comprises a frame 310 to which the disks 320 are fixed in position by clamps 330 which clamp onto the edges of the holes in the center of the disks. (Note that the inner edges of the disk are not used in the final product, since this is where the spindle is attached to the disk. This is in contrast to the outer edge of the disk which is used in the HDD and therefore must be properly patterned.) The frame 310 and the clamps 330 are configured to make good electrical contact to the disks 320. The holders may be stacked one above another in the chamber to enable high throughput.

Further details of plasma ion implantation chambers and process methods are available in U.S. Pat. Nos. 7,288,491 and 7,291,545 to Collins et al., incorporated by reference herein. The primary difference between the chamber of the present invention and the chamber of Collins et al. is the different configuration for holding the substrates. The disk holders of the present invention allow implantation of both sides at once, whereas the substrates in Collins et al. sit on a wafer chuck during processing. Those skilled in the art will appreciate how the plasma ion implantation tools and methods of Collins et al. can be utilized in the present invention.

Following the plasma ion implantation step 130 is the resist strip step 140. The resist strip step 140 can be facilitated by a descum and ash in the plasma ion implantation chamber prior to removing the disks. The resist strip step 140 may be a wet chemical process, well known in the art.

The present invention is not restricted to HDDs, but is applicable to other magnetic memory devices such as magnetoresistive random access memories (MRAMs). Those skilled in the art will appreciate how the present invention can be used to define the magnetic memory elements of the MRAM.

The present invention allows for very short process times—perhaps ten seconds to implant the disks. Input and output vacuum loadlocks will enable rapid transfer of disks in and out of the chamber and avoid losing time for pumpdown, thus allowing for very high throughput. Those skilled in the art will appreciate how automated transfer systems, robotics and loadlock systems can be integrated with the plasma ion implantation apparatus of the present invention.

Although the present invention has been particularly described with reference to the preferred embodiments thereof, it should be readily apparent to those of ordinary skill in the art that changes and modifications in the form and details may be made without departing from the spirit and scope of the invention. It is intended that the appended claims encompass such changes and modifications.

What is claimed is:

1. A method for defining magnetic domains in a magnetic thin film on a substrate, comprising the steps of:
coating said magnetic thin film with a resist;
patterning said resist, wherein areas of said magnetic thin film are substantially uncovered; and
exposing said magnetic thin film to a plasma, wherein plasma ions penetrate said substantially uncovered areas of said magnetic thin film, rendering said substantially uncovered areas non-magnetic.

2. The method of claim 1, wherein said patterning is nanoimprint patterning.

3. The method of claim 1, wherein said plasma comprises oxygen, fluorine, boron, phosphorus, tungsten, arsenic, hydrogen, helium, argon, nitrogen, carbon or silicon ions.

4. The method of claim 1, further comprising, after exposing said magnetic thin film to a plasma, annealing said magnetic thin film, whereby the implanted ions are driven to a desired depth in said magnetic thin film.

5. The method of claim 4, wherein said anneal is implemented by a laser.

6. The method of claim 1, further comprising, after said exposing step, stripping said resist.

7. The method of claim 1, wherein said plasma is generated by connecting a radio frequency generator between said magnetic thin film and a vacuum chamber wall, said substrate being positioned in a vacuum chamber.

8. The method of claim 7, wherein said exposing said magnetic thin film to said plasma includes applying a direct current bias between said thin film and said vacuum chamber wall.

9. The method of claim 7, wherein said exposing said magnetic thin film to said plasma includes applying a radio frequency bias between said thin film and said vacuum chamber wall.

10. A method for defining magnetic domains on thin film magnetic media disks, comprising the steps of:
coating both sides of said disks with a resist;
patterning said resist, wherein areas of said magnetic thin film are substantially uncovered; and
simultaneously exposing said magnetic thin film on both sides of said disk to a plasma, wherein plasma ions penetrate said substantially uncovered areas of said magnetic thin film, rendering said substantially uncovered areas non-magnetic.

11. The method as in claim 10, wherein said patterning is nanoimprint patterning.

12. The method as in claim 11, wherein said patterning is on both sides of said disk at once.

13. A tool for plasma implant treatment of thin film magnetic media disks, said disks having central circular apertures, comprising:
a vacuum chamber held at earth potential;
a gas inlet valve configured to leak controlled amounts of gas into said chamber;
a disk mounting device configured to (1) fit within said chamber, (2) hold a multiplicity of disks, making contact with each of said multiplicity of disks at the corresponding central circular aperture and spacing said multiplicity of disks wherein both sides of each of said multiplicity of disks is exposed and (3) make electrical contact to said multiplicity of disks; and
a radio frequency signal generator electrically coupled to said disk mounting device and said chamber, whereby a plasma can be ignited in said chamber and said disks are exposed to plasma ions uniformly on both sides.

14. A tool as in claim 13, wherein said disk mounting device is a rod, said rod having a diameter less than the central aperture of said disks.

15. A tool as in claim 14, wherein said disks are fixed to said rod by clamps, each of said clamps being configured to hold one of said disks in place on said rod and to provide an electrical connection between said one of said disks and said rod.

16. A tool as in claim 13, wherein said disk mounting device is a frame configured to hold a plurality of disks in a single plane.

17. A tool as in claim 13, wherein said disk mounting device is a multiplicity of frames, each frame being configured to hold a plurality of disks, said frames being positioned in parallel planes.

18. A tool as in claim 16, wherein said frame includes clamps attaching to the central circular apertures of said disks, each of said clamps being configured to hold one of said disks in place on said frame and to provide an electrical connection between said one of said disks and said rod.

19. A tool as in claim 13, further comprising a voltage supply electrically coupled to said disk mounting device and said chamber, said voltage supply being configured to hold said mounting device at a DC bias with respect to said chamber wall.

20. The method of claim 13, wherein said radio frequency signal generator is configured to apply a radio frequency bias between said thin film and said vacuum chamber wall.
